(19) United States
(12) Patent Application Publication
(10) Pub. No.: US 2013/0195599 A1
(43) Pub. Date: Aug. 1, 2013

(54) ROBOT

(71) Applicant: KABUSHIKI KAISHA YASKAWA DENKI, Fukuoka (JP)

(72) Inventors: Masatoshi Furuichi, Fukuoka (JP); Shinichi Katsuda, Fukuoka (JP)

(73) Assignee: KABUSHIKI KAISHA YASKAWA DENKI, Fukuoka (JP)

(21) Appl. No.: 13/733,959

(22) Filed: Jan. 4, 2013

(30) Foreign Application Priority Data
Feb. 1, 2012 (JP) 2012-020273

(51) Int. Cl. H01L 21/677

(52) U.S. Cl. CPC H01L 21/677
USPC 414/744.5

(57) ABSTRACT

A robot includes an arm unit having a base end portion rotatably installed through a joint part. The arm unit includes a housing and a specified member arranged within the housing. At least a portion of the housing is made of a transparent material.

### CROSS-REFERENCE TO RELATED APPLICATION

The present disclosure contains subject matter related to that disclosed in Japanese Priority Patent Application No. 2012-020273 filed on Feb. 1, 2012. The contents of this application are incorporated herein by reference in their entirety.

### BACKGROUND OF THE INVENTION

1. Field of the Invention

An Embodiment disclosed herein relates to a robot.

2. Description of the Related Art

Conventionally, a so-called horizontal articulated robot is known as a robot for transferring a substrate such as a semiconductor wafer or the like. In the horizontal articulated robot, a hand serving as an end effecter is installed in the tip end portion of a swingable arm so as to horizontally rotate with respect to the arm. The hand is capable of holding a substrate (see, e.g., Japanese Patent Application Publication No. 2011-224743).

In the robot of this type, a hand drive mechanism for driving the hand is usually arranged within a housing of the arm. A sensor for detecting the existence and absence of a substrate is installed in the hand. An electric cable is sometimes arranged within the housing of the arm.

In the conventional configuration stated above, however, when an attempt is made to check up, e.g., the hand drive mechanism or the cables, it is impossible to check the internal state of the arm without removing the cover attached to the arm housing.

### SUMMARY OF THE INVENTION

In accordance with an aspect of the present embodiment, there is provided a robot, including: an arm unit having a base end portion rotatably installed through a joint part, the arm unit including a housing and a specified member arranged within the housing, wherein at least a portion of the housing is made of a transparent material.

### BRIEF DESCRIPTION OF THE DRAWINGS

FIG. 1 is a schematic explanatory view showing a robot according to the present embodiment.

FIG. 2 is a schematic explanatory vertical section view showing a second arm of the robot.

FIG. 3 is an explanatory view showing a window portion installed in the second arm of the robot.

FIG. 4 is an explanatory view showing a modified example of the window portion.

### DESCRIPTION OF THE EMBODIMENTS

One embodiment of a robot disclosed herein will now be described in detail with reference to the accompanying drawings which form a part hereof. While a horizontal articulated robot will be described below as one example of the robot, the present invention is not limited to the embodiment to be described below.

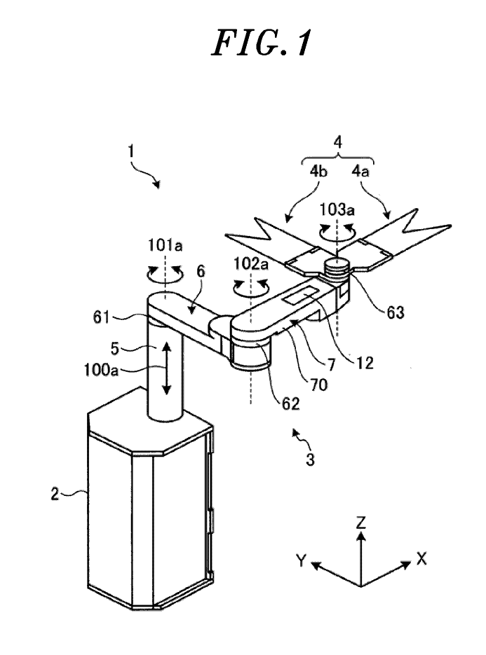

First, the schematic configuration of a horizontal articulated robot (hereinafter simply referred to as “robot 1”) according to the present embodiment will be described with reference to FIG. 1. FIG. 1 is a schematic explanatory view showing a robot 1 according to the present embodiment.

In the following description, it is sometimes the case that the relative positional relationships of the respective components of the robot 1 are defined by an up-down direction, a left-right direction and a front-rear direction. In this case, the Z-direction in the three-dimensional rectangular coordinate system shown in FIG. 1 will be referred to as an upward direction, the X-direction as a horizontal right direction and the Y-direction as a front direction.

Referring to FIG. 1, the robot 1 according to the present embodiment includes a base unit 2 installed on a specified installation surface such as a floor surface or the like and an arm unit 3 installed to horizontally rotate with respect to the base unit 2. The arm unit 3 is provided at its tip end with a hand unit 4 rotatable in the horizontal direction.

The base unit 2 is a base of the robot 1. A lift mechanism (not shown) for driving a lift unit 5 that moves the arm unit 3 up and down is arranged within the base unit 2. For example, a well-known mechanism employing a motor and a ball screw can be used as the lift mechanism.

The arm unit 3 is installed to be slidable in the vertical direction (the Z-direction) with respect to the upper surface of the base unit 2 by way of the lift unit 5 formed into a columnar shape (see a double-headed arrow 100a in FIG. 1).

The arm unit 3 includes a first arm 6 and a second arm 7. The first arm 6 has a base end portion installed at the upper end of the lift unit 5 through a first joint part 61 to be horizontally rotatable about a center axis 101a.

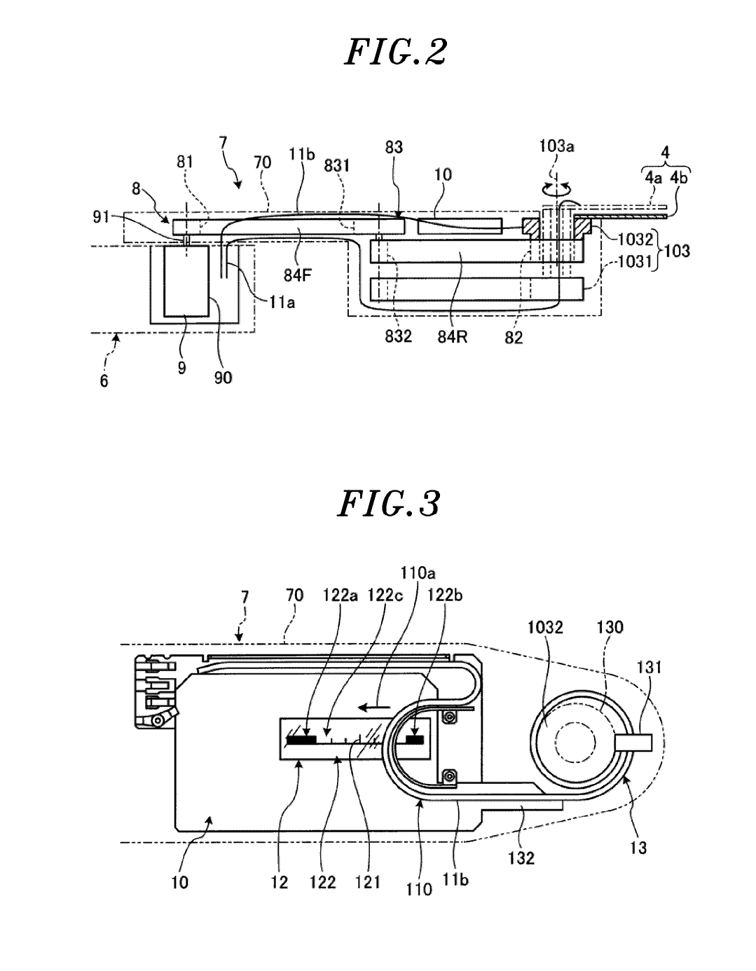

The second arm 7 has a base end portion installed in a tip end portion of the first arm 6 through a second joint part 62 to be horizontally rotatable about a center axis 102a. The hand unit 4 is installed in a tip end portion of the second arm 7 through a hand pivot shaft 103 (see FIG. 2) of a third joint part 63 to be rotatable about a center axis 103a.

The hand unit 4 is an end effecter for holding, e.g., a wafer. The hand unit 4 includes a first hand 4a and a second hand 4b, both of which are formed into a fork shape.

The first hand 4a and the second hand 4b are installed in a spaced-apart relationship along the hand pivot shaft 103. In other words, the first hand 4a and the second hand 4b are attached to the hand pivot shaft 103 in a vertically overlapping state so as to be independently rotatable within a specified rotation extent.

As shown in FIG. 1, the first hand 4a and the second hand 4b have the same configuration. Alternatively, the first hand 4a and the second hand 4b may have different configurations. In the present embodiment, the hand unit 4 is configured to include two hands, but the number of the hands is not limited thereto.

The robot 1 is installed in, e.g., a substrate transfer system (not shown) and can be appropriately used in transferring a substrate such as a wafer or the like. The substrate transfer system is installed side by side with a processing apparatus for subjecting a substrate to, e.g., cleaning, etching, ashing, chemical vapor deposition or exposing. Needless to say, a plurality of robots 1 may be installed at different points so as to transfer a plate-like member such as a substrate or the like between desired positions.

Next, the configuration of the second arm 7 of the robot 1 will be described in detail with reference to FIGS. 2 through 4.

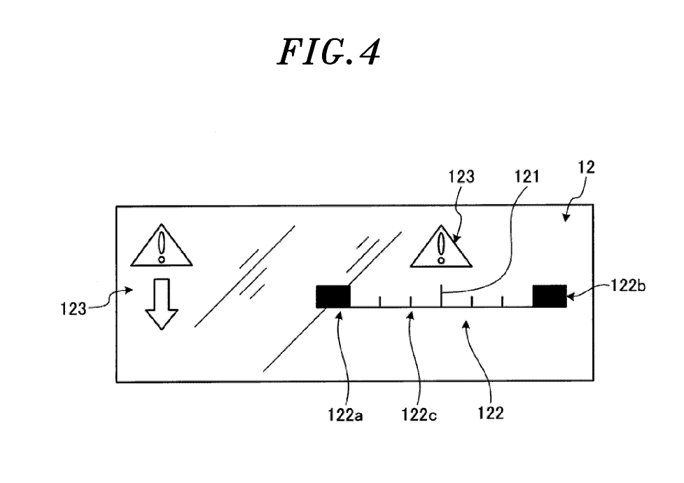

FIG. 2 is a schematic explanatory vertical section view showing the second arm 7 of the robot 1. FIG. 3 is an explanatory view showing a window portion 12 installed in the second arm 7 of the robot 1. FIG. 4 is an explanatory view showing a modified example of the window portion 12.

As shown in FIGS. 1 and 2, the second arm 7 of the robot 1 has a specified length and includes a box-shaped arm housing 70 as an outer shell. The opposite end portions of the arm housing 70 are formed of substantially semicircular circumferential surfaces. One half portion of the arm housing 70 near the tip end thereof has a specified thickness. Another half portion of the arm housing 70 near the base end thereof is formed to have a thickness smaller than the specified thickness.

As shown in FIG. 1, the second arm 7 is rotatably connected to the tip end portion of the first arm 6 through the second joint part 62. As shown in FIG. 2, a hand drive mechanism 8 for driving the hand pivot shaft 103 at a reduced speed is arranged within the arm housing 70.

As shown in FIG. 2, the hand pivot shaft 103 of the present embodiment includes a first hand pivot shaft 1031 to which the first hand 4a is connected and a second hand pivot shaft 1032 to which the second hand 4b is connected. In other words, the first hand pivot shaft 1031 formed into a tubular shape is inserted into the second hand pivot shaft 1032 formed into a tubular shape with an inner diameter larger than the outer diameter of the first hand pivot shaft 1031. The first hand pivot shaft 1031 and the second hand pivot shaft 1032 have a common center axis 103a.

The hand drive mechanism 8 includes a mechanism corresponding to the first hand 4a and a mechanism corresponding to the second hand 4b, both of which have substantially the same configuration. The mechanism corresponding to the second hand 4b will now be described as the hand drive mechanism 8 with reference to FIG. 2. The description on the mechanism corresponding to the first hand 4a will be omitted.

The hand drive mechanism 8 corresponding to the second hand 4b includes a motor 9, a driving pulley 81 attached to a drive shaft 91, i.e., a motor shaft, of the motor 9 and a driven pulley 82 having a specified speed reduction ratio, which is directly attached to the second hand pivot shaft 1032. The hand drive mechanism 8 further includes an intermediate pulley 83 having a specified speed reduction ratio, which is arranged between the driving pulley 81 and the driven pulley 82, and a plurality of first belts for operatively interconnecting the driving pulley 81 and the driven pulley 82 through the intermediate pulley 83.

As shown in FIG. 2, the intermediate pulley 83 includes a driving intermediate pulley 831 and a driving sub-pulley 832 arranged just below the driving intermediate pulley 831. The driving intermediate pulley 831 and the driving pulley 81 are operatively connected to each other through a front-end power-transmitting belt 84F. On the other hand, the driving sub-pulley 832 and the driven pulley 82 are operatively connected to each other through a rear-end power-transmitting belt 84R.

As shown in FIG. 2, the motor 9 includes a motor base end portion 90 arranged within the first arm 6. The upper portion of the drive shaft 91 of the motor 9 extends into the arm housing 70 of the second arm 7. This assists in reducing the thickness of the second arm 7. However, if there is no need to reduce the thickness of the arm housing 70, the motor base end portion 90 of the motor 9 need not be necessarily arranged within the first arm 6. In other words, the motor 9 may be arranged within the second arm 7.

In the robot 1 according to the present embodiment, as described above, the hand drive mechanism 8 for driving the first hand 4a and the second hand 4b with specified torque is arranged within the arm housing 70 of the second arm 7.

For example, sensors for detecting the presence or absence of a substrate are installed in the first hand 4a and the second hand 4b. First and second cables 11a and 11b are connected to the sensors.

More specifically, as shown in FIG. 2, the first cable 11a coming from the first hand 4a extends toward the first arm 6 through the inside of the first hand pivot shaft 1031 having a tubular shape. The second cable 11b coming from the second hand 4b extends toward the first arm 6 through the inside of a cable handling space 10 which is defined between the hand drive mechanism 8 arranged within the second arm 7 and the upper surface of the arm housing 70. In this manner, the first and second cables 11a and 11b for interconnecting the hand unit 4 and the base unit 2 are arranged within the arm housing 70 of the robot 1 according to the present embodiment.

As shown in FIG. 3, a cable winder 13 capable of preventing entanglement of the second cable 11b extending from the second hand 4b into the cable handling space 10 while restraining rotation of the second hand 4b is installed within the arm housing 70.

The cable winder 13 is configured to wind the second cable 11b in response to the rotation of the second hand pivot shaft 1032. More specifically, as shown in FIG. 3, the cable winder 13 includes an annular winding portion 130 installed to be rotatable together with the second hand pivot shaft 1032 and a connecting body 131 connected to the second cable 11b and protruded from the winding portion 130.

If the second hand 4b is rotated, e.g., counterclockwise in FIG. 3, the second cable 11b is moved through a cable passage 132 and is wound around the annular winding portion 130.

On the other hand, if the second hand 4b is rotated clockwise, the second cable 11b wound around the annular winding portion 130 is unwound into the cable handling space 10 through the cable passage 132. At this time, the curved portion 110 of the second cable 11b is moved inward of the cable handling space 10 (see an arrow 110a in FIG. 3).

In this manner, the second cable 11b is introduced into the cable handling space 10 within which the cable winder 13 is arranged, thereby preventing the second cable 11b from being unnecessarily loosened. Accordingly, it is possible to prevent the second cable 11b from being twisted during rotation of the second hand 4b and to assure smooth movement of the second cable 11b. It is also possible to limit the rotation amount of the second hand 4b.

In the robot 1 of the present embodiment configured as above, as shown in FIG. 1, a window portion 12 made of a transparent material is installed on the upper surface of the arm housing 70 of the second arm 7 so that at least a portion of the second cable 11b can be visually recognized through the window portion 12. In other words, the position of the second cable 11b wound or unwound by the cable winder 13 can be visually recognized through the window portion 12.

As the transparent material of which the window portion 12 is made, it is possible to use, e.g., a resin such as an acryl resin or a polycarbonate resin or a reinforced glass.

In the present embodiment, the window portion 12 is arranged so that the position of the curved portion 110 of the second cable 11b within the cable handling space 10 can be visually recognized through the window portion 12. By visually recognizing the position of the curved portion 110 of the second cable 11b in this manner, it is possible to easily check up the movement of the second cable 11b from the outside of the arm housing 70.

As shown in FIG. 3, an indicator portion 122 having a specified scale 121 is provided in the transparent material of which the window portion 12 is made.

A cable position permitting zone 122c indicating a permission extent of movement of the second cable 11b is defined in the indicator portion 122.

In the indicator portion 122 according to the present embodiment, abnormal zones 122a and 122b are defined at the left and right sides of the cable position permitting zone 122c. More specifically, if the second hand 4b is rotated beyond a limited rotation amount, the curved portion 110 of the second cable 11b is positioned in a position deviated from the cable position permitting zone 122c, i.e., in one of the abnormal zones 122a and 122b. This can be recognized at a single glance from the outside.

By installing the window portion 12 in the second arm 7 and visually recognizing the movement of the second cable 11b through the window portion 12, it is possible to easily determine whether the second hand 4b is rotated beyond the limited rotation amount.

Since the abnormality of the second cable 11b can be readily found from the outside, it is possible to check up the second cable 11b when a trouble occurs and to carry out appropriate emergency maintenance in a timely manner.

As shown in FIG. 4, one or more marks 123 indicating a checkup region within the arm housing 70 may be formed in the transparent material of which the window portion 12 is made.

Due to the existence of the marks 123, an inspector who wishes to visually recognize a plurality of checkup regions through one window portion 12 can easily understand which of the regions of the window portion 12 has to be paid with attention.

For example, depending on the structure of the cable handling space 10, the window portion 12 may be formed so that the belts of the hand drive mechanism 8 arranged at the lower side can be visually recognized. In that case, one of the marks 123 (positioned at the left side in FIG. 4) may be arranged to indicate a visual recognition region for checking up the belts and the other mark 123 may be arranged to indicate a visual recognition region for checking up the second cable 11b.

With this configuration, not only the second cable 11b but also the hand drive mechanism 8 can be checked up through the single window portion 12. By appropriately arranging the marks 123, an inspector, either an expert or a novice, can perform necessary checkup tasks with no omission.

The marks 123 and the indicator portion 122 may not be directly formed in the transparent material such as a resin or a glass but may be formed in the regions within the arm housing 70 which can be visually recognized through the transparent material.

In order to check the inside of the arm through the window portion 12 according to the present embodiment, it is necessary for an inspector to observe the inside of the arm from just above the window portion 12. For example, a mirror or a prism may be arranged within the arm housing 70 so that the inside of the arm can be visually recognized from the obliquely upper side of the window portion 12. With this configuration, even if a significant stature difference exists between inspectors, it is possible for the respective inspectors to enjoy visual recognition.

The installation position of the window portion 12 is not limited to the position where the curved portion 110 of the second cable 11b is located. A suitable number of window portions 12 may be installed in different regions where there is a need to see and check the inside of the arm housing 70.

In the robot 1 according to the present embodiment, the window portion 12 is installed on the upper surface of the arm housing 70 of the second arm 7. However, no restriction is imposed on the installation target arm, the installation position and the installation number. For example, the window portion 12 may be installed in other arms having a specified member arranged therein, e.g., the first arm 6.

The installation position and installation number of the window portion 12 can be set arbitrarily. As long as it is possible to visually see and check a specified member arranged within the arm, at least a portion of the arm housing 70 may be made of a transparent material.

Inasmuch as at least a portion of the arm housing 70 may be made of a transparent material without having to install the window portion 12, it is thinkable to form the arm housing 70 with a skeleton structure made of a transparent reinforced resin or a reinforced glass having a required strength.

As described above, with the robot 1 according to the present embodiment, it is easy to visually recognize the second cable 11b and the hand drive mechanism 8, which are arranged within the arm housing 70, through the window portion 12 from the outside. Accordingly, it is possible to determine, through the observation of the second cable 11b, whether the position of the second hand 4b is proper before starting a work. It is also possible to maintain the second cable 11b and the hand drive mechanism 8 in a timely manner.

In the robot 1 described above, the base end portion of the second arm 7 is rotatably attached to the first arm 6 through the second joint part 62. The hand pivot shaft 103 as an output shaft is installed in the tip end portion of the second arm 7. The hand drive mechanism 8 for driving the hand pivot shaft 103 at a reduced speed is arranged within the second arm 7.

However, the output shaft is not limited to the hand pivot shaft 103. As a matter of course, any other drive mechanism capable of driving the output shaft may be used in place of the hand drive mechanism 8. It goes without saying that the arm for accommodating such a drive mechanism is not limited to the second arm 7. In other words, it is only necessary that the window portion 12 enables an inspector to visually recognize the state of the members arranged within the arm. The installation position of the window portion 12 may be arbitrarily changed as necessary.

The arm unit 3 is not limited to the type capable of rotating horizontally through the joint parts. The arm unit may be rotated horizontally and vertically or may be rotated only vertically. In the event that the arm unit 3 is rotated only vertically, only the hand unit 4 as an end effecter may be allowed to rotate horizontally.

Other effects and other modified examples can be readily derived by those skilled in the art. For that reason, the broad aspect of the present disclosure is not limited to the specific disclosure and the representative embodiment shown and described above. Accordingly, the present disclosure can be modified in many different forms without departing from the spirit and scope defined by the appended claims and the equivalents thereof.

What is claimed is:

1. A robot, comprising:
an arm unit having a base end portion rotatably installed through a joint part, the arm unit including a housing and a specified member arranged within the housing,
wherein at least a portion of the housing is made of a transparent material.

2. The robot of claim 1, wherein said at least a portion of the housing is a window portion made of the transparent material.

3. The robot of claim 1, wherein the housing includes an indicator portion having a specified scale, the indicator portion being formed in the transparent material or in a region visually recognizable through the transparent material.

4. The robot of claim 3, wherein the indicator portion has a zone indicating a change permitting extent of the member arranged within the housing.

5. The robot of claim 1, wherein a mark indicating a checkup region existing within the arm unit is formed in the transparent material or in a region visually recognizable through the transparent material.

6. The robot of claim 1, wherein the arm unit has a tip end portion to which a hand unit is rotatably attached through a hand pivot shaft, and
the robot further comprises: a cable arranged within the housing to interconnect the hand unit and a base unit installed on a specified installation surface, at least a portion of the cable existing in a region visually recognizable through the transparent material.

7. The robot of claim 6, wherein the arm unit further includes a hand drive mechanism arranged within the housing to drive the hand unit, the arm unit having a cable handling space defined between the hand drive mechanism and the upper surface of the housing, the cable being introduced into the cable handling space such that the cable is visually recognizable through the transparent material.

8. The robot of claim 1, wherein the transparent material is positioned on the upper surface of the housing.

9. The robot of claim 7, wherein the arm unit further includes a cable winder for winding the cable introduced into the cable handling space response to rotation of the hand pivot shaft, the position of the cable wound or unwound by the cable winder being visually recognizable through the transparent material.

10. The robot of claim 6, wherein the arm unit includes a first arm having a base end portion rotatably attached through a first joint part to a base unit installed on a specified installation surface and a second arm having a base end portion rotatably attached to a tip end portion of the first arm through a second joint part, the second arm having a tip end portion to which a hand unit is rotatably attached through a hand pivot shaft, the transparent material being positioned in a housing of the second arm.
